(19) United States
(12) Patent Application Publication
(10) Pub. No.: US 2005/0176209 A1
(43) Pub. Date: Aug. 11, 2005

(54) Embedded passive components

(75) Inventors: Jon D. Jorgenson, Greensboro, NC (US); Milind Shah, Greensboro, NC (US); Victor E. Steel, Oak Ridge, NC (US)

Correspondence Address: WITHROW & TERRANOVA, P.L.L.C., P.O. BOX 1287, CARY, NC, 27512, US

(73) Assignee: RF Micro Devices, Inc., Greensboro, NC (US)

(21) Appl. No.: 10/366,924

(22) Filed: Feb. 14, 2003

(51) Int. Cl. H01L 21/20; G06F 17/50; H01L 29/00

(52) U.S. Cl. 438/381; 716/1; 257/528

(57) ABSTRACT

The present invention embeds passive components within a multilayer substrate used for mounting integrated circuits and other electronic components to form an electronic module or circuit board. During construction of the multilayer substrate, passive components are attached to an inside surface of a metallic foil layer. The inside surface of the metallic foil layer is then laminated to another metallic foil layer, such that the foil layers are parallel to but separated from each other. As such, the passive component is embedded within the multilayer substrate. Contacts are formed for the passive component by etching away portions of the foil layer on which the passive component resides. Electrical connections can be routed in the foil to effectively couple the passive component to a circuit formed on the multilayer substrate as desired. The embedded passive components can take various forms, such as capacitors, inductors, and resistors.

### FIELD OF THE INVENTION

The present invention relates to substrate design for integrated circuit modules and printed circuit boards, and in particular to embedding passive components therein.

### BACKGROUND OF THE INVENTION

Integrated circuits and passive components are routinely placed on substrates to implement electronic circuits. Given the continuing desire to minimize the size of the substrates and minimize the cost of manufacturing the same, there is a need to embed passive components within the substrate. Embedding passive components within the substrate provides more room for routing circuit traces between those components that reside on the outer surface of the substrate, as well as minimizing the amount of surface area needed to implement such electronic circuits. In radio frequency applications, placement of embedded components, capacitors in particular, often has significant impact on circuit performance, and embedding components within the substrate provides greater flexibility in component placement. Further, given the increasing need to reduce the cost of electronic circuits in commercial applications, there is a need to reduce the cost associated with placing and connecting these relatively small passive components during manufacturing.

### SUMMARY OF THE INVENTION

The present invention embeds passive components within a multilayer substrate used for mounting integrated circuits and other electronic components to form an electronic module or circuit board. During construction of the multilayer substrate, the passive component is attached to an inside surface of a metallic foil layer. The inside surface of the metallic foil layer is then laminated to another metallic foil layer, such that the foil layers are parallel to but separated from each other. As such, the passive component is embedded within the multilayer substrate. Contacts are formed for the passive component by etching away portions of the foil layer on which the passive component resides. Electrical connections can be routed in the foil to effectively couple the passive component to a circuit formed on the multilayer substrate as desired. The embedded passive component can take various forms, such as capacitors, inductors, and resistors. Preferably, the components are silk screened onto the inside surface of the metallic foil layer. The invention is applicable to multilayer substrates of two or more metallic foil layers.

Those skilled in the art will appreciate the scope of the present invention and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the invention, and together with the description serve to explain the principles of the invention.

FIGS. 1-4 and 6-11 illustrate a preferred process for embedding passive components in a multilayer, circuit board substrate according to a preferred embodiment of the present invention.

FIGS. 5A-5E illustrate a process for creating a capacitor on a metal layer of the substrate according to one embodiment of the present invention.

FIG. 5F illustrates placement of multiple capacitors formed according to the steps of 5A-5E on one layer of the substrate.

FIGS. 12A and 12B illustrate the placement of multiple embedded passive components on one layer of the substrate according to one embodiment of the present invention.

### DETAILED DESCRIPTION OF THE PREFERRED EMBODIMENTS

The embodiments set forth below represent the necessary information to enable those skilled in the art to practice the invention and illustrate the best mode of practicing the invention. Upon reading the following description in light of the accompanying drawing figures, those skilled in the art will understand the concepts of the invention and will recognize applications of these concepts not particularly addressed herein. It should be understood that these concepts and applications fall within the scope of the disclosure and the accompanying claims. Further, the illustrations in the accompanying figures are not to scale.

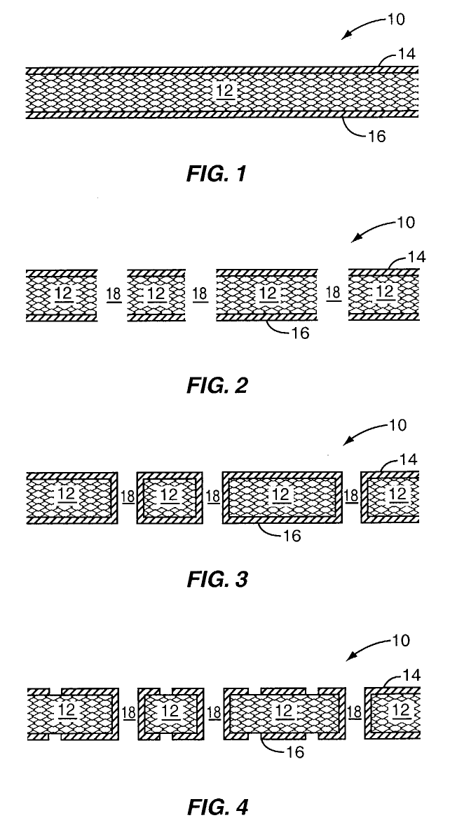

The present invention embeds passive components within the multilayer substrate used for mounting integrated circuits and other components to form an electronic module or circuit board. The embedded components are constructed within the substrate in a manner allowing more surface area for additional components and connection routing. In a preferred embodiment, semiconductor die, along with other components, are placed on either or both of the outer surfaces of the substrate. Wire bonding is used to connect electrical connections on the semiconductor die to electrical traces running to other components. An exemplary architecture and process for embedding passive components in a substrate is illustrated in association with FIGS. 1-12B.

With reference to FIG. 1, the process is initiated by providing a core 10 formed from a central core material 12, such as glass epoxy, sandwiched between two layers of metallic foil 14 and 16. For solely the purposes of clarity, the described embodiment ultimately forms a substrate having four foil layers, and as such, the foil layers 14 and 16 are herein respectively referred to as layer 2 (L2) foil 14 and layer 3 (L3) foil 16. In this embodiment, the foil layers are preferably copper, but may be formed from any metallic material capable of supporting high temperature processing.

Based on the desired connectivity and circuit topology, core vias 18 may be drilled through the core material 12 as illustrated in FIG. 2. Preferably, the core vias 18 are plated with a seed layer of copper to provide cylindrical side walls lining the core vias 18 as illustrated in FIG. 3. Based on the desired electrical connectivity, patterns may be etched onto the surface of and through the L2 and L3 foils 14, 16 to provide the necessary electrical connectivity or isolation, as illustrated in FIG. 4.

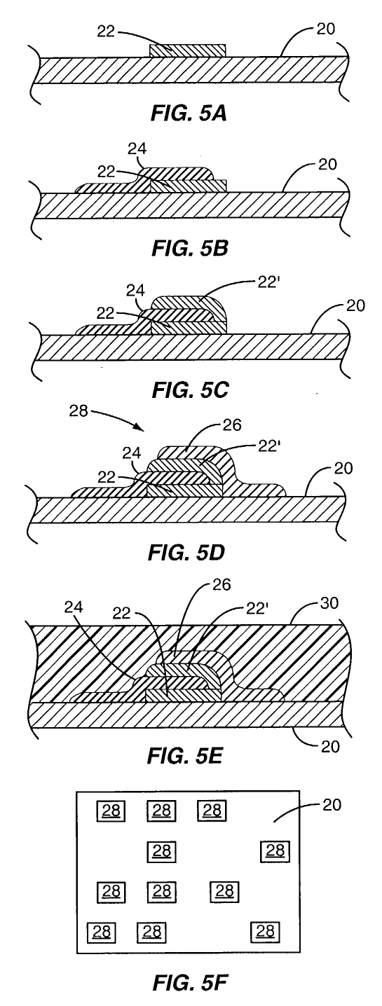

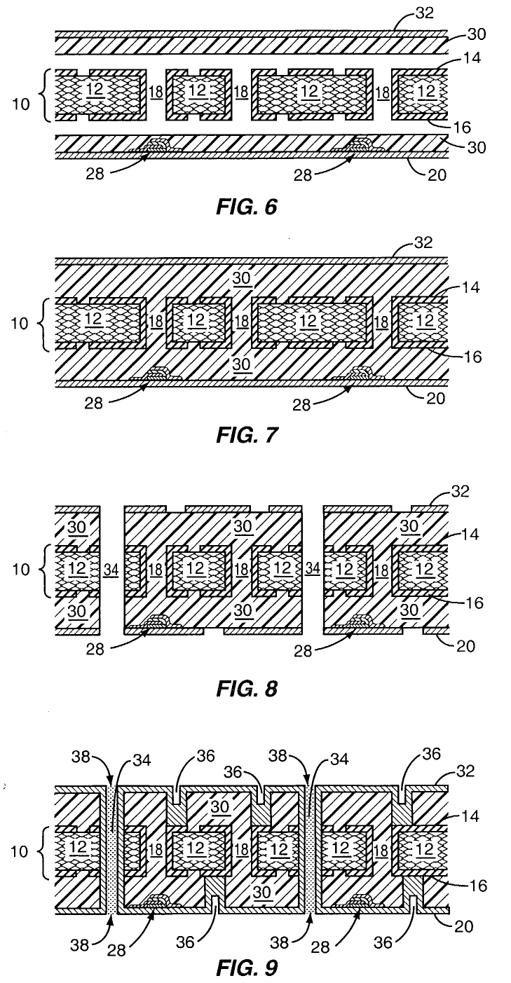

Next, an outside metallic foil layer, preferably the bottom or layer 4 (L4) foil 20, is provided and conditioned for the placement of embedded passive components on the side of the L4 foil 20 to be attached to the core 10. Although any type of passive component can be implemented according to the techniques described herein, the preferred and illustrated embodiment provides one or more capacitors on what will become the inside surface of the L4 foil 20, as illustrated in FIGS. 5A-5E. In this embodiment, the embedded capacitors are effectively screen printed onto the inside surface of the L4 foil 20. Initially, a conditioning paste, such as copper, is printed through a 400 # screen over the entire surface of the L4 foil 20. The L4 foil is dried at 150° C. and fired at 900° C. in a Nitrogen environment using a one-hour profile. As illustrated in FIGS. 5A-5E, sequential screen printing steps are used to form alternating electrode and dielectric layers to effectively form a substantially parallel plate capacitor. The electrode layers are formed using an electrode paste, which is screen printed onto the surface of the L4 foil 20 or another layer of the capacitor. Similarly, the dielectric layers are formed by screen printing a dielectric paste onto the L4 foil 20 or another layer forming the capacitor. Notably, sputtering or other acceptable layering process may be used to form the embedded components. Further, the components may be separately formed and then placed.

With particular reference to FIG. 5A, a first dielectric layer 22 is formed by screen printing a dielectric paste in the shape and location desired for providing a capacitance within the substrate. Next, a first metal layer 24 is provided on top of and substantially covering the first dielectric layer 22. As illustrated in FIG. 5B, the first metal layer 24 may extend past the edge of the first dielectric layer 22, so as to contact the surface of the L4 foil 20, providing a point of electrical connection to the L4 foil 20. Next, a second dielectric layer 22′ is formed on top of the first metal layer 24 by screen printing a dielectric paste on top of the first metal layer 24, as illustrated in FIG. 5C. The first and second dielectric layers 22, 22′ can be any type of dielectric material, with an example being Barium Titanate. Preferably, the dielectric paste forming the second dielectric layer 22′ rolls over the edge of the first metal layer 24 to come into electrical contact with the first dielectric layer 22. Thus, a substantial portion of the first metal layer 24 is sandwiched between the first and second dielectric layers 22 and 22′.

A second metal layer 26 is added on top of the second dielectric layer 22′, and preferably extends down to and comes in contact with the L4 foil 20 to provide a second contact for the capacitor, as illustrated in FIG. 5D. The first and second metal layers 24, 26 are preferably copper. Thus, the capacitor is formed by the first and second metal layers 24, 26 being parallel to each other and separated by the second dielectric layer 22′. The first dielectric layer 22 isolates the capacitor from a portion of the L4 foil 20. The parts of the first and second metal layers 24, 26 that extend to the surface of the L4 foil 20 are the contacts for the capacitor to the L4 foil 20. Later in the process, these contacts are electrically isolated from one another by etching away a portion of the L4 foil 20 to effectively provide electrical isolation between the first and second metal layers 24, 26 and form a capacitor 28. Once the capacitor or capacitors 28 are formed, a filler material 30, which is generically referred to as pre-preg glass epoxy, is provided over the surface of the L4 foil 20 containing the embedded components, such as the capacitors 28. Preferably, the filler material 30 also effectively covers the embedded components, as illustrated in FIG. 5E. Notably, multiple embedded components, such as the capacitors 28, may be provided in different sizes, shapes, and placements over the entire surface of the L4 foil 20 as illustrated in FIG. 5F.

Turning now to FIG. 6, the core 10 is next sandwiched between the L4 foil 20 and a metallic layer 1 (L1) foil 32. Notably, the L1 foil 32 will also include filler material 30 on an inside surface, and as such, each of the L1 and L4 foils 32, 20 are pressed against the respective sides of the core 10. In one embodiment, the filler material 30 is woven glass fiber embedded in a resin. During application of the L1 and L4 foils 32, 20 to the core 10, the structure is heated and the L1 and L4 foils 32, 20 are pressed against the respective sides of the core 10 such that the filler material 30 comes in contact with and fills any voids in the core 10, such as the core vias 18. Once cooled, the L1-L4 foils 32, 14, 16, 20 form a four-layer laminated substrate, as illustrated in FIG. 7. Notably, the L3 and L4 foils 16, 20 are spaced apart a sufficient amount to prevent the passive components on the L4 foil 20 from coming into contact with the L3 foil 16.

With reference to FIG. 8, through vias 34 may be drilled as necessary through the substrate in addition to conformal etching through the L1 and L4 foils 32, 20 in preparation for drilling micro-vias. As shown in FIG. 9, micro-vias 36 are drilled through the filler material 30 to the L2 and L3 foils 14, 16 from the L1 and L4 foils 32, 20, respectively. Next, the through vias 34 and micro-vias 36 are plated with copper, and the through vias 34 are plugged with a plugging ink 38 or like plugging material such as non-conductive epoxy used for plugging. Notably, the plating of the through vias 34 not only lines the cylindrical walls of the micro-vias 36, but also forms a cylindrical contact with the outer surfaces of the L2 and L3 foils 14, 16.

Turning now to FIG. 10, the outside surfaces of the L1 and L4 foils 32, 20 are covered with a plating layer 40, which is formed of copper, to essentially cover the entire outer surfaces of the L1 and L4 foils 32, 20 and cap the through vias 34 and the micro-vias 36. Next, an etching pattern 42 is applied to the outer surfaces of the L1 and L4 foils 32, 20. The etching pattern 42 will define the circuit traces that will be etched into the L1 and L4 foils 32, 20 as shown in FIG. 11. Notably, the etching process will effectively isolate, from the L4 foil's perspective, the respective contacts for the embedded passive components, such as the capacitor 28. Thus, the contacts of the embedded passives are no longer shorted after the etching process, and a capacitance is formed between the contacts.

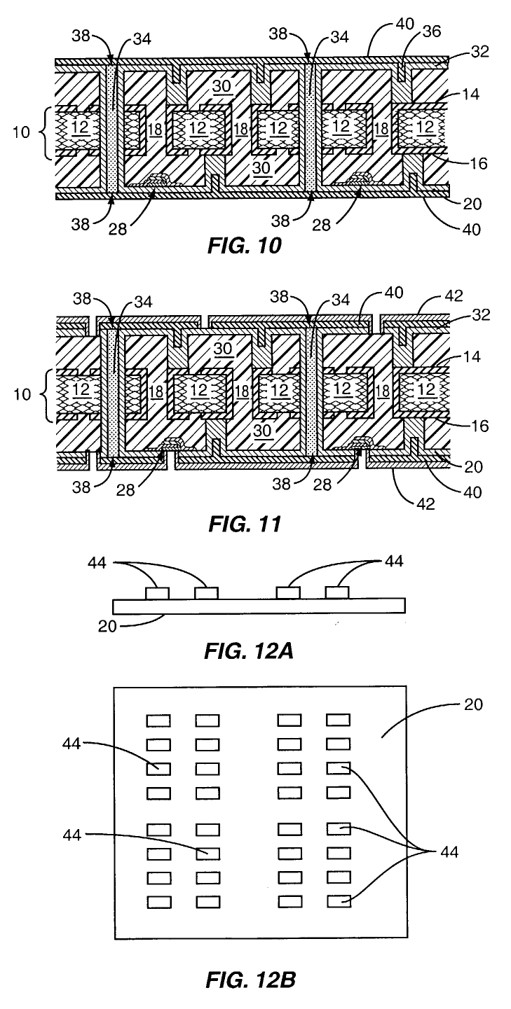

As illustrated in FIGS. 12A and 12B, although an exemplary process and architecture is shown with capacitors 28, resistors and other passive components 44 may be embedded in the substrate as described above. For instance, many different kinds and types of embedded passives may be placed on one surface of the L4 foil 20 according to the needs of the desired circuit. As such, capacitors 28 and resistors made of resistive material may be formed within the substrate. Further, the substrate may have any number of layers, and the embedded passives may be placed on any layer.

Those skilled in the art will recognize various types of passive components, such as capacitors, inductors, and resistors, that can be embedded as described above. Further, those skilled in the art will recognize various ways to form and connect these components to the inside surfaces of one of the two outer foil layers 14, 16. Those skilled in the art will also recognize improvements and modifications to the preferred embodiments of the present invention. All such improvements and modifications are considered within the scope of the concepts disclosed herein and the claims that follow.

1. A method for embedding passive components in a multilayer substrate comprising:
a) providing a core comprising a core material between parallel second and third foil layers;
b) providing first and fourth foil layers having an inside surface;
c) placing a passive component on the inside surface of the fourth foil layer;
d) attaching the first foil layer to the core with a filler material wherein the inside surface of the fourth foil layer is spaced apart from the second foil layer; and
e) attaching the fourth foil layer to the core with the filler material wherein the inside surface of the fourth foil layer is spaced apart from the third foil layer, wherein the first, second, third, and fourth foil layers form a multilayer substrate.

2. The method of claim 1 further comprising removing a portion of the fourth foil layer about the passive component to form isolated contacts and connections thereto for the embedded component in the fourth foil layer.

3. The method of claim 2 further comprising removing further portions of the first foil layer to form electrical connections for components to be placed on an outside surface of the first foil layer and for the embedded component.

4. The method of claim 3 wherein the removing steps comprise etching away the portions of the first and fourth foil layers.

5. The method of claim 2 further comprising removing further portions of the fourth foil layer and portions of the first foil layer to form electrical connections for components to be placed on outside surfaces of the first and fourth foil layers.

6. The method of claim 1 wherein the passive component is a capacitor.

7. The method of claim 6 wherein the attaching step comprises silk screening the capacitor onto the inside surface of the fourth foil layer.

8. The method of claim 7 wherein the silk screening step further comprises:
a) silk screening a first dielectric material on a first area on the inside surface of the fourth foil layer;
b) silk screening a first metallic layer substantially over the first dielectric layer and extending to a second area adjacent the first area on the inside surface of the fourth foil layer;
c) silk screening a second dielectric layer substantially over the first metallic layer and extending into contact with a portion of the first dielectric layer; and
d) silk screening a second metallic layer substantially over the second dielectric layer and extending to a third area adjacent the first area on the inside surface of the fourth foil layer, the second and third areas spaced apart from each other and corresponding to isolated contacts for the capacitor.

9. The method of claim 1 wherein the attaching step comprises:
a) layering a first dielectric material on a first area on the inside surface of the fourth foil layer;
b) layering a first metallic layer substantially over the first dielectric layer and extending to a second area adjacent the first area on the inside surface of the fourth foil layer;
c) layering a second dielectric layer substantially over the first metallic layer and extending into contact with a portion of the first dielectric layer; and
d) layering a second metallic layer substantially over the second dielectric layer and extending to a third area adjacent the first area on the inside surface of the fourth foil layer, the second and third areas spaced apart from each other and corresponding to isolated contacts for a capacitor.

10. The method of claim 1 wherein the passive component is a resistor.

11. The method of claim 1 wherein the passive component is an inductor.

12. The method of claim 1 further comprising forming electrical connections between portions of the fourth and third foil layers.

13. The method of claim 12 further comprising forming electrical connections between portions of the third and second foil layers.

14. The method of claim 12 further comprising forming electrical connections between portions of the first and fourth foil layers.

15. The method of claim 1 wherein the fourth foil layer is an outside layer of the multilayer substrate.

16. A multilayer substrate with embedded passive components comprising parallel first, second, third, and fourth foil layers separated by a non-conductive material to form the multilayer substrate, the fourth foil layer having the passive component placed on an inside surface thereof.

17. The multilayer substrate of claim 16 wherein a portion of the fourth foil layer is removed about the passive component to form isolated contacts and connections thereto for the embedded passive component in the fourth foil layer.

18. The multilayer substrate of claim 17 wherein portions of the first foil layer are removed to form electrical connections for components to be placed on an outside surface of the first foil layer.

19. The multilayer substrate of claim 18 wherein portions of the first and fourth foil layers are removed using an etching process.

20. The multilayer substrate of claim 17 wherein portions of the fourth foil layer and portions of the first foil layer are removed to form electrical connections for components to be placed on outside surfaces of the first and fourth foil layers and for the passive component.

21. The multilayer substrate of claim 16 wherein the passive component is a capacitor.

22. The multilayer substrate of claim 21 wherein the capacitor is silk screened to the inside surface of the fourth foil layer.

23. The multilayer substrate of claim 21 wherein the capacitor comprises:
a) a first dielectric material on a first area on the inside surface of the fourth foil layer;
b) a first metallic layer substantially over the first dielectric layer and extending to a second area adjacent the first area on the inside surface of the fourth foil layer;
c) a second dielectric layer substantially over the first metallic layer and extending into contact with a portion of the first dielectric layer; and
d) a second metallic layer substantially over the second dielectric layer and extending to a third area adjacent the first area on the inside surface of the fourth foil layer, the second and third areas spaced apart from each other and corresponding to isolated contacts for the capacitor.

24. The multilayer substrate of claim 16 wherein the passive component is a resistor.

25. The multilayer substrate of claim 16 wherein the passive component is an inductor.

26. The multilayer substrate of claim 16 further comprising electrical connections between portions of the fourth and third foil layers.

27. The multilayer substrate of claim 26 further comprising electrical connections between portions of the third and second foil layers.

28. The multilayer substrate of claim 26 further comprising electrical connections between portions of the first and fourth foil layers.

29. The multiplayer substrate of claim 16 wherein the fourth foil layer is an outside layer of the multilayer substrate.

30. A method for embedding passive components in a multilayer substrate comprising:
a) providing first and second foil layers;
b) placing a passive component on an inside surface of the first foil layer;
c) attaching the first foil layer to the second foil layer with a filler material wherein the inside surface of the first foil layer is spaced apart from the second foil layer; wherein the first and second foil layers form a multilayer substrate.

31. A multilayer substrate with embedded passive components comprising parallel first and second foil layers separated by a non-conductive material to form the multilayer substrate, the first foil layer having a passive component placed on an inside surface thereof.
